(19) United States
(12) Patent Application Publication
(10) Pub. No.: US 2025/0336027 A1
(43) Pub. Date: Oct. 30, 2025

(54) CHIP, DATA PROCESSING METHOD AND DEVICE

(71) Applicant: Smarter Silicon (Shanghai) Technologies Co., Ltd., Shanghai (CN)

(72) Inventor: Xinghai BAO, Shanghai (CN)

(21) Appl. No.: 19/194,068

(22) Filed: Apr. 30, 2025

(30) Foreign Application Priority Data
Apr. 30, 2024 (CN) 202410546594.X

(51) Int. Cl. G06T 1/60; G06T 1/20

(52) U.S. Cl. CPC G06T 1/60; G06T 1/20

(57) ABSTRACT

A chip includes a first processor, a slice buffer and a second processor. An output of the first processor is connected to an input of the slice buffer and an input of the second processor respectively. An output of the slice buffer is connected to the input of the second processor. The first processor is configured to write slice data into the slice buffer after the slice data has been processed, and transmit an interrupt signal to the second processor. The second processor being configured to read the slice data from the slice buffer based on the interrupt signal, and process the slice data to obtain corresponding result data.

### CROSS-REFERENCES TO RELATED APPLICATION

This application claims priority to Chinese Patent Application No. 202410546594.X filed on Apr. 30, 2024, the entire content of which is incorporated herein by reference.

### FIELD OF TECHNOLOGY

The present disclosure relates to a chip, a data processing method, and a data processing device.

### BACKGROUND

When performing video image processing, artificial intelligence reasoning can be used to realize functions such as recognition of object types in video images, object segmentation, and classification of video images. At present, artificial intelligence reasoning is performed in a frame-based manner. Generally, the size of frame data is relatively large. In the 4K (3840×2160) YUV420 format, the size is 11.8 Mbyte (3840×2160×1.5 byte). Since the frame data is relatively large, there is a need to interact with an external storage unit, which causes memory access delays and extended AI reasoning time.

### SUMMARY

One aspect of this disclosure provides a chip. The chip includes a first processor, a slice buffer and a second processor. An output of the first processor is connected to an input of the slice buffer and an input of the second processor respectively, and an output of the slice buffer is also connected to the input of the second processor. The first processor is configured to write slice data into the slice buffer after the slice data has been processed, and transmit an interrupt signal to the second processor. The second processor is configured to read the slice data from the slice buffer based on the interrupt signal, and process the slice data to obtain corresponding result data.

Another aspect of this disclosure provides a data processing method. The data processing method includes, writing, by a first processor, slide data into a slice buffer, and transmit an interrupt signal to a second processor after completing a corresponding data processing on the slice data; and reading, by the second processor, the slice data from the slice buffer based on the interrupt signal, and processing the slice data to obtain corresponding result data.

Another aspect of this disclosure provides a data processing device. The data processing device includes a writing unit, a transmission unit, a reading unit and a processing unit. The writing unit is configured to cause a first processor to write slice data into a slice buffer after the slice data has been processed by corresponding data. The transmission unit is configured to transmit an interrupt signal to a second processor. The reading unit is configured to cause the second processor to read the slice data from the slice buffer based on the interrupt signal. The processing unit is configured to process the slice data to obtain corresponding result data.

### BRIEF DESCRIPTION OF THE DRAWINGS

FIG. 1 is a schematic diagram of an image signal processing (ISP) process according to some embodiments of the present disclosure.

FIG. 2 is a schematic diagram of the ISP process according to some embodiments of the present disclosure.

FIG. 3 is a schematic structural diagram of a chip according to some embodiments of the present disclosure.

FIG. 4 is a schematic structural diagram of an example slice buffer according to some embodiments of the present disclosure.

FIG. 5 is a schematic structural diagram of an example chip according to some embodiments of the present disclosure.

FIG. 6 is a schematic structural diagram of an example data image post-processing structure based on system-level cache according to some embodiments of the present disclosure.

FIG. 7 is a delay comparison diagram of an example frame-based data processing process and a slice-based data processing process according to some embodiments of the present disclosure.

FIG. 8 is a flowchart of a data processing method according to some embodiments of the present disclosure.

FIG. 9 is a schematic structural diagram of a data processing device according to some embodiments of the present disclosure.

### DETAILED DESCRIPTION

The features and technical solutions of present disclosure are described in detail with reference to the accompanying drawings in the accompanying drawings. The accompany drawings are for illustrative purposes and are not intended to limit the present disclosure.

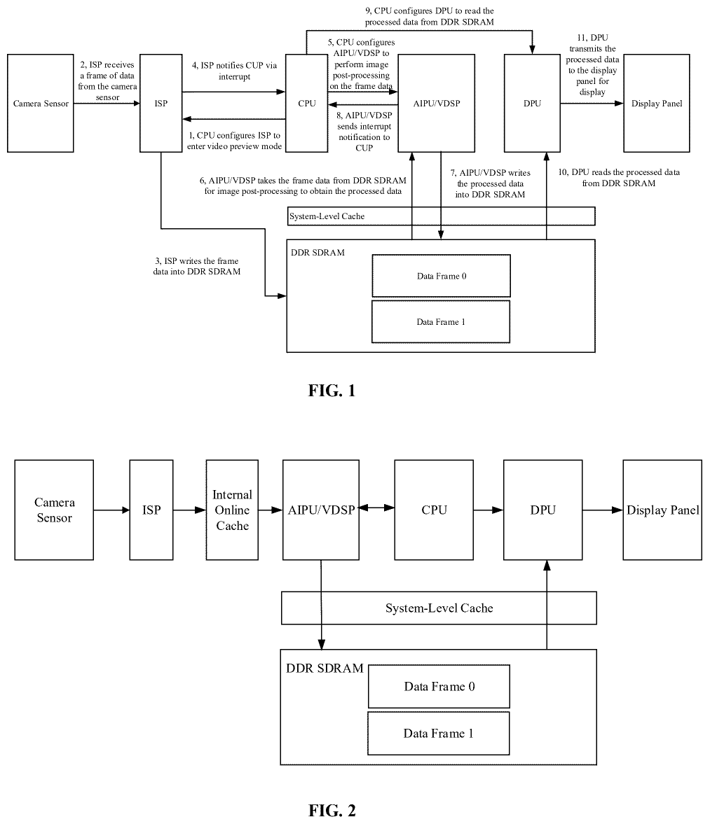

FIG. 1 is a schematic diagram of a current image signal processing (ISP) process. The process will be described in detail below.
1, central processing unit (CPU) configures ISP to enter video preview mode.
2, ISP receives a frame of data from the camera sensor.
3, ISP writes the frame data into the double data rate (DDR) synchronous dynamic random-access-memory (SDRAM).
4, ISP notifies the CPU via interrupt.
5, CPU configures an artificial intelligence processor unit (AIPU)/vision digital signal processor (VDSP) to perform image post-processing on the frame data.
6, AIPU/VDSP takes the frame data from DDR SDRAM for image post-processing to obtain the processed data.
7, AIPU/VDSP writes the processed data into the DDR SDRSM.
8, AIPU/VDSP sends interrupt notification to the CPU.
9, CPU configures the DPU to read the processed data from the DDR SDRSM.
10, DPU reads the processed data from the DDR SDRAM.
11, DPU transmits the processed data to the display panel for display.

The method above uses data frames as the smallest unit for interaction. AIPU/VDSP post-processing needs to wait for a complete frame of data to be written before it can start post-processing. Take 30 fps as an example, the minimum delay is greater than 1/30s.

In the method above, the data frame is stored in the DDR SDRAM, and the data interaction of image post-processing must go through the DDR SDRAM, resulting in memory access delay and power consumption greater than internal RAM.

In the method above, the data frame is stored in the smallest unit, which results in a large cache space. Take the 4K (i.e., 3840×2160) YUV420 format as an example, the size of one frame of image is 11.8 Mbyte (i.e., 3840×2160×1.5 byte).

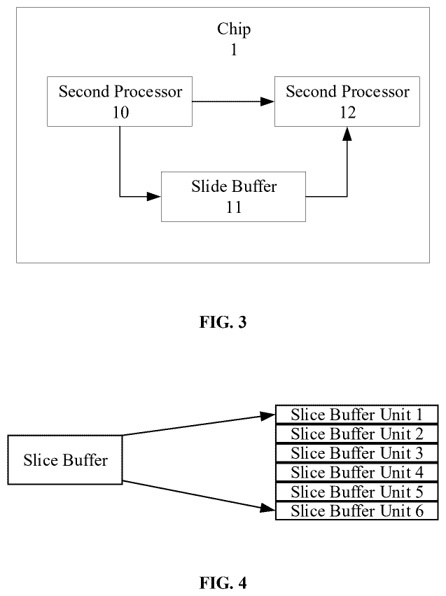

To improve the memory access delay and high power consumption caused by storing data frames in the DDR SDRAM, embodiments of the present disclosure provide a new ISP process. FIG. 2 is a schematic diagram of the ISP process according to some embodiments of the present disclosure.

Referring to FIG. 2, an internal online cache is added on the communication link between the ISP and the AIPU/VDSP. The ISP and AIPU/VDSP may use this internal online cache to perform tightly coupled data interaction to reduce access to the DDR SDRAM, but this internal online cache is exclusive to ISP and AIPU/VDSP. When the communication link between the ISP and AIPU/VDSP is disabled, chip area is wasted.

It should be noted that the locations of memory data access by the ISP and AIPU/VDSP in FIG. 2 and FIG. 1 are different, but the other implementation steps are the same and will not be repeated here.

To improve the memory access delay and high power consumption caused by storing data frames in the DDR SDRAM, embodiments of the present disclosure provide a chip. FIG. 3 is a schematic structural diagram of a chip according to some embodiments of the present disclosure. As shown in FIG. 3, the chip 1 includes a first processor 10, a slice buffer 11 and a second processor 12. The output of the first processor 10 is connected to the input end of the slice buffer 11 and the input of the second processor 12 respectively, and the output of the slice buffer 11 is also connected to the input of the second processor 12. The first processor 10 may be configured to write the slice data into the slice buffer 11 after the slice data has been processed, and transmit an interrupt signal to the second processor 12. The second processor 12 may be configured to read the slice data from the slice buffer 11 based on the interrupt signal, and process the slice data to obtain the corresponding result data.

It should be noted that in the embodiments of the present disclosure, the data processing may be data processing performed in the scenario of video processing or image processing. In actual applications, the specific data processing scenario may be determined based on the actual situation, which is not limited in the embodiments of the present disclosure.

In some embodiments, in the video processing scenario, the first processor may be a video processing unit, the second processor may be an AIPU, and the corresponding slice data may be video slice data; in an image processing scenario, the first processor may be an image processing unit, the second processor may be an AIPU, and the corresponding slice data may be image slice data.

In some embodiments, the video processing unit may be a video processing unit (VPU) and the image processing unit may be an ISP.

In some embodiments, the slice buffer may include a plurality of slice buffer units. The slice buffer may use a write pointer to mark the location where data is written. The write pointer may point to one of the slice buffer units (equivalent to the target slice buffer unit of the present disclosure), and the first processor may write the slice data into the slice buffer unit pointed to by the write pointer in the slice buffer. When a preset condition is met, the first processor may generate an interrupt signal and transmit the interrupt signal to the second processor.

In some embodiments, the interrupt signal may be a trigger signal for the second processor to start image post-processing and read slice data from the slice buffer. After receiving the interrupt signal, the second processor may trigger the start of the image post-processing process and the process of reading slice data from the slice buffer.

It can be understood that the interrupt signal can be directly used as the start trigger signal of the subsequent second processor. The process does not need to be transferred to the CPU for triggering, which reduces the number of devices involved in the data processing process, simplifies the data processing process, and improves the data processing efficiency.

In some embodiments, the first processor may include a comparison unit and a statistical unit. The first processor may use the comparison unit and the statistical unit to generate the interrupt signal. More specifically, the statistical unit may be used to obtain a statistical parameter of the data currently processed by the first processor. The comparison unit may be used to compare the statistical parameter with a preset segmentation parameter and generate an interrupt signal when the preset condition is met.

In some embodiments, the preset segmentation parameter may be determined based on the total number of data contained in a frame and a preset number of slices.

In some embodiments, if the split dimension splits the data by row, the statistical unit may obtain the statistical parameter as the number of data rows; the corresponding preset split parameter may be the preset row count; the comparison unit may compare the number of rows with a preset row count. If the number of rows is the same as the preset row count, it may indicate that the preset condition is met, and an interrupt signal can be generated.

In some embodiments, the preset segmentation parameter may be determined based on the total number of rows contained in a frame of data and the preset number of slices.

Take the 4K (3840×2160) format as an example, the preset number of slices is 6, and the preset segmentation parameter is set to 3840/6=640.

In some embodiments, if the split dimension splits the data by column, the statistical unit may obtain the statistical parameter as the number of columns of the data column; the corresponding preset split parameter may be the preset column count; the comparison unit may compare the column number with a preset column count. If the column number is the same as the preset column count, it may indicate that a preset condition is met, and an interrupt signal can be generated.

In some embodiments, the preset segmentation parameter may be determined based on the total number of columns contained in a frame of data and the preset number of slices.

Take the 4K (3840×2160) format as an example, the preset number of slices is 6, and the preset segmentation parameter is set to 2160/6=360.

It should be understood that the segmentation parameter may be pre-configured, and different segmentation parameters may be configured to adapt to data processing requirements of different resolutions, thereby improving the intelligence of data processing.

It should be noted that the data segmentation by row and data segmentation by column described above are only two examples. The specific method can be selected based on the actual segmentation dimension, which is not limited in the embodiments of the present disclosure.

In some embodiments, the slice buffer may include a plurality of slice buffer units.

In some embodiments, the first processor may sequentially write the slice data into the target slice buffer unit pointed to by the write pointer. When the target slice buffer unit is full, the write pointer may point to the next slice buffer unit of the target slice buffer unit, and the read pointer may point to the target slice buffer unit. The second processor may read the slice data in the target slice buffer unit pointed to by the read pointer.

In some embodiments, the slice buffer may also use a read pointer to mark the location where data is read. The first processor may write the slice data sequentially into the target slice buffer unit pointed to by the write pointer. When the target slice buffer unit is full, the write pointer may point to the next slice buffer unit of the target slice buffer unit, the read pointer may point to the target slice buffer unit, and the first processor may generate an interrupt signal and send the interrupt signal to the second processor. The second processor may read the slice data in the target slice buffer unit pointed to by the read pointer.

FIG. 4 is a schematic structural diagram of an example slice buffer according to some embodiments of the present disclosure. Refer to FIG. 4, a slice buffer may include six slice buffer units, namely, slice buffer unit 1 to slice buffer unit 6, and the data frame may be divided into a plurality of slice data and stored in each slice buffer unit of the slice buffer respectively.

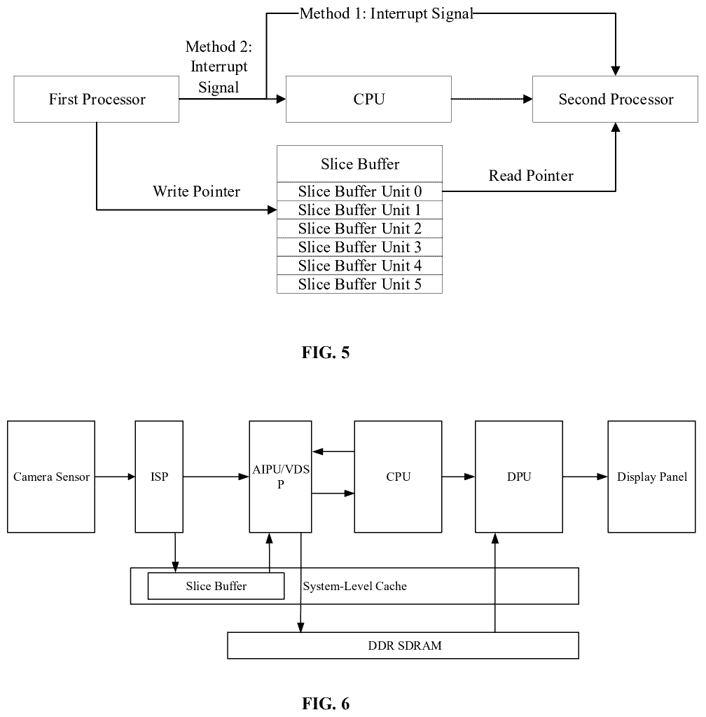

FIG. 5 is a schematic structural diagram of an example chip according to some embodiments of the present disclosure. As shown in FIG. 5, the read pointer points to the slice buffer unit 0 of the slice buffer, and the second processor performs data reading in the slice buffer unit 0; the write pointer points to the slice buffer unit 1 of the slice buffer, and the first processor performs data writing in the slice buffer unit 1. When slice buffer unit 1 is full, the write pointer moves to slice buffer unit 2 to perform subsequent data write operations, and the read pointer moves to slice buffer unit 1 to perform subsequent data read operations.

In some embodiments, the slice buffer may include a plurality of slice buffer units, each of which stores slice data.

In some embodiments, the first processor may be configured to return to the first slice buffer unit in the slice buffer to perform a next slice data writing operation after writing the slice data to the last slice buffer unit in the slice buffer.

It should be noted that, for the slice buffer, the first processor may store data cyclically. That is, when the last slice buffer unit of the slice buffer reaches the maximum capacity, new data will be stored starting from the first slice buffer unit of the slice buffer to form a cycle. This cyclical storage method can fully utilize the space of the slice buffer and avoid data overflow or waste.

In some embodiments, when the communication link between the first processor and the second processor is started, a portion of the cache in the system-level cache may be used as a slice buffer.

Part of the cache in the system-level cache may be used as the slice buffer. Accordingly, in the process that the first processor writing the slice data and the second processor reading the slice data, the memory access to the DDR SDRSM can be reduced, thereby reducing power consumption and improving data processing efficiency.

Refer to FIG. 6. Part of the system-level cache is a slice buffer. The ISP writes slice data to the slice buffer in the system-level cache, and the AIPU/VDSP reads slice data from the slice buffer in the system-level cache.

It should be noted that the locations of memory data accessed by the ISP and the AIPU/VDSP in FIG. 6 and FIG. 1 are different, and the other implementation steps are the same, which will not be repeated here.

It should be noted that, when the communication link between the first processor and the second processor is not enabled, part of the cache used as a slice buffer in the system-level cache may be released such that the space of the system-level cache can be released when the communication link between the first processor and the second processor is not enabled, thereby reducing the space waste of the system-level cache.

In some embodiments, the chip may also include a CPU. The input of the CPU may be connected to the output end of the first processor, and the output of the CPU may be connected to the input end of the second processor. The first processor may be used to transmit the interrupt signal to the CPU. The CPU may be configured to generate a read position for the slice buffer based on the interrupt signal, and the second processor may be configured to read the slice data from the reading position.

Refer to FIG. 5. The interrupt signal can be sent using the following methods. In the first method, the ISP sends the interrupt signal directly to the AIPU/VDSP. In the second method, the ISP sends the interrupt signal to the CPU, and the CPU controls the AIPU/VDSP to start image post-processing and read slice data from the read position.

It should be noted that the above two methods of sending the interrupt signal are examples method of sending the interrupt signal in this present disclosure, and specific methods can be selected based on actual conditions, which are not limited in the embodiments of the present disclosure.

It should be understood that the data is divided into slice data. Since the slice data is small, a slice buffer can be integrated in the chip to cache the slice data. At this time, the second processor can perform data processing based on the size of the slice data as the basic unit. The second processor can directly read the slice data from the inside of the chip, which can reduce the data acquisition overhead and the storage requirements for data space during the data processing process. The second processor does not need to wait for a frame of data to be received before executing data processing. Accordingly, data processing can be started in parallel for slice data, which reduces access delays and shortens data processing time.

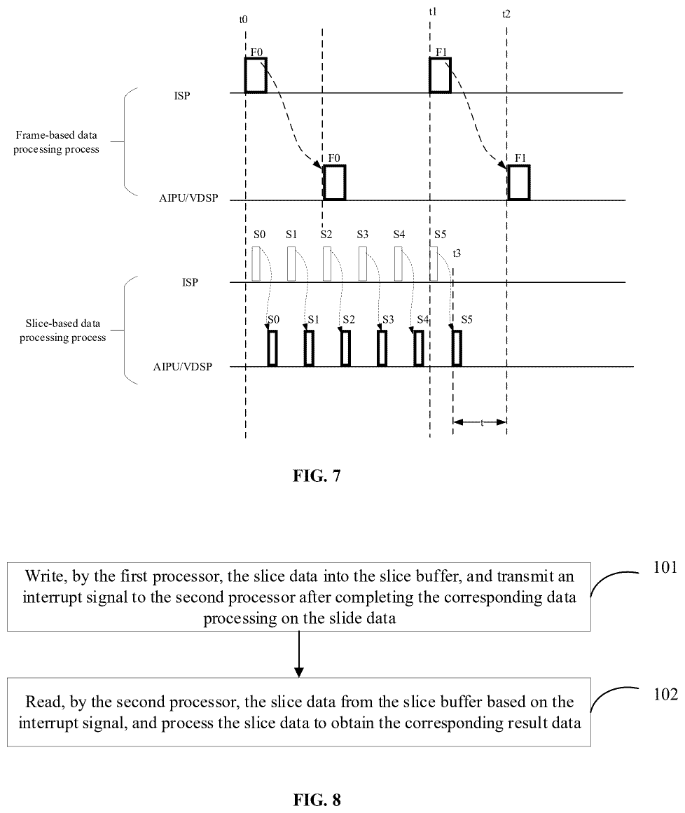

FIG. 7 is a delay comparison diagram of an example frame-based data processing process and a slice-based data processing process according to some embodiments of the present disclosure. As shown in FIG. 7, in the frame-based data processing process, at time t0, the ISP starts writing to data frame F0. At time t1, the frame interrupt signal triggers the CPU to schedule the AIPU/VDSP to start post-processing F0. At time t2, the AIPU/VDSP completes the processing of F0. In the slice-based data processing process, a frame of data is divided into 6 slices of data. Starting at time to, slice data S0, S1, S2, S3, S4, and S5 of F0 are written in sequence. After each slice of data is written, the AIPU/VDSP performs the reading and post-processing process of the slice data. The post-processing of the 6 slices of F0 is completed at time t3. It can be seen from FIG. 7, t2 is greater than t3 by t, which indicates that the slice-based data processing process has a smaller latency than the frame-based data processing process.

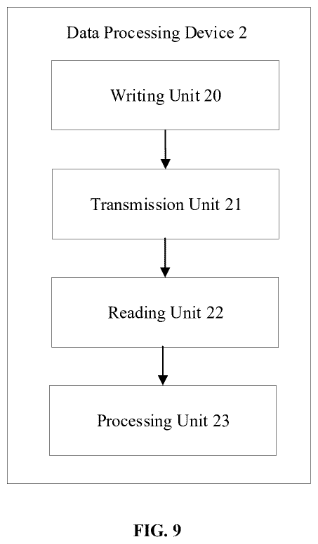

FIG. 8 is a flowchart of a data processing method according to some embodiments of the present disclosure. The method will be described in detail below.

101, writing, by the first processor, the slice data into the slice buffer and transmitting an interrupt signal to the second processor after completing the corresponding data processing on the slide data.

102, reading, by the second processor, the slice data from the slice buffer based on the interrupt signal, and processing the slice data to obtain the corresponding result data.

It should be noted that in the embodiments of the present disclosure, the data processing may be data processing performed in the scenario of video processing or image processing. In actual applications, the specific data processing scenario may be determined based on the actual situation, which is not limited in the embodiments of the present disclosure.

In some embodiments, in the video processing scenario, the first processor may be a video processing unit, the second processor may be an AIPU, and the corresponding slice data may be video slice data; in an image processing scenario, the first processor may be an image processing unit, the second processor may be an AIPU, and the corresponding slice data may be image slice data.

In some embodiments, before the first processor transmits the interrupt signal to the second processor, the first processor may also perform an operation of generating the interrupt signal, which may be implemented based on a statistical unit and a comparison unit in the first processor. More specifically, the statistical unit may be configured to obtain the statistical parameters of the data row currently processed by the first processor, and the comparison unit may be configured to compare the statistical parameters with the preset segmentation parameter. When the preset conditions are met, an interrupt signal may be generated.

It should be noted that the preset segmentation parameter may be determined according to the total number of data included in a frame and a preset number of slices.

In some embodiments, if the split dimension splits the data by row, the statistical unit may obtain the statistical parameter as the number of data rows; the corresponding preset split parameter may be the preset row count; the comparison unit may compare the number of rows with a preset row count. If the number of rows is the same as the preset row count, it may indicate that the preset condition is met, and an interrupt signal can be generated.

In some embodiments, the preset segmentation parameter may be determined based on the total number of rows contained in a frame of data and the preset number of slices.

Take the 4K (3840×2160) format as an example, the preset number of slices is 6, and the preset segmentation parameter is set to 3840/6=640.

In some embodiments, if the split dimension splits the data by column, the statistical unit may obtain the statistical parameter as the number of columns of the data column; the corresponding preset split parameter may be the preset column count; the comparison unit may compare the column number with a preset column count. If the column number is the same as the preset column count, it may indicate that a preset condition is met, and an interrupt signal can be generated.

In some embodiments, the preset segmentation parameter may be determined based on the total number of columns contained in a frame of data and the preset number of slices.

Take the 4K (3840×2160) format as an example, the preset number of slices is 6, and the preset segmentation parameter is set to 2160/6=360.

It should be understood that the segmentation parameter may be pre-configured, and different segmentation parameters may be configured to adapt to data processing requirements of different resolutions, thereby improving the intelligence of data processing.

It should be noted that the data segmentation by row and data segmentation by column described above are only two examples. The specific method can be selected based on the actual segmentation dimension, which is not limited in the embodiments of the present disclosure.

In some embodiments, the CPU may also be used to transmit an interrupt signal generated by the first processor to the second processor. For example, the first processor transmits an interrupt signal to the CPU; the CPU generates a read position for the slice buffer according to the interrupt signal; then the second processor reads the slice data from the read position.

Refer to FIG. 5. The interrupt signal can be sent using the following methods. In the first method, the ISP sends the interrupt signal directly to the AIPU/VDSP. In the second method, the ISP sends the interrupt signal to the CPU, and the CPU controls the AIPU/VDSP to start image post-processing and read slice data from the read position.

It should be noted that the above two methods of sending the interrupt signal are examples method of sending the interrupt signal in this present disclosure, and specific methods can be selected based on actual conditions, which are not limited in the embodiments of the present disclosure.

In some embodiments, the slice buffer may use two pointers, namely the write pointer and the read pointer, to mark the location where data is written and the location where data is read respectively. The write pointer may point to the target slice buffer unit, and the first processor may write the slice data sequentially into the target slice buffer unit pointed to by the write pointer until the target slice buffer unit is full. Then the write pointer may point to the next slice buffer unit of the target slice buffer unit. The read pointer may point to the target slice buffer unit, and the first processor may generate an interrupt signal and send the interrupt signal to the second processor. The second processor may read the slice data in the target slice buffer unit pointed to by the read pointer

It should be noted that the slice buffer may include a plurality of slice buffer units. If the last slice buffer unit in the slice buffer is full, the first processor may return to the first slice buffer unit in the slice buffer to perform the next slice data writing operation. More specifically, if the last slice buffer unit in the slice buffer is full, the write pointer may point to the first slice buffer unit in the slice buffer to ensure that the first processor writes the next slice data in the first slice buffer unit.

In some embodiments, when the communication link between the first processor and the second processor is enabled, a portion of the system-level cache may be used as a slice buffer.

In some embodiments, when the communication link between the first processor and the second processor is started, part of the cache may be applied from the system-level cache as a slice buffer, or part of the cache may be reserved by the system-level cache as a slice buffer.

Part of the cache in the system-level cache may be used as the slice buffer. Accordingly, in the process that the first processor writing the slice data and the second processor reading the slice data, the memory access to the DDR SDRSM can be reduced, thereby reducing power consumption and improving data processing efficiency.

It should be noted that, when the communication link between the first processor and the second processor is not enabled, part of the cache used as a slice buffer in the system-level cache may be released such that the space of the system-level cache can be released when the communication link between the first processor and the second processor is not enabled, thereby reducing the space waste of the system-level cache.

It should be understood that the data is divided into slice data. Since the slice data is small, a slice buffer can be integrated in the chip to cache the slice data. At this time, the second processor can perform data processing based on the size of the slice data as the basic unit. The second processor can directly read the slice data from the inside of the chip, which can reduce the data acquisition overhead and the storage requirements for data space during the data processing process. The second processor does not need to wait for a frame of data to be received before executing data processing. Accordingly, data processing can be started in parallel for slice data, which reduces access delays and shortens data processing time.

FIG. 9 is a schematic structural diagram of a data processing device according to some embodiments of the present disclosure. As shown in FIG. 2, the data processing device 2 includes writing unit 20, a transmission unit 21, a reading unit 22 and a processing unit 23.

In some embodiments, the writing unit 20 may be configured to cause the first processor to write the slice data into the slice buffer after the slice data has been processed.

In some embodiments, the transmission unit 21 may be configured to transmit the interrupt signal to the second processor.

In some embodiments, the reading unit 22 may be configured to cause the second processor to read the slice data from the slice buffer based on the interrupt signal.

In some embodiments, the processing unit 23 may be configured to process the slice data to obtain the corresponding result data.

In some embodiments, the data processing device may further include a statistical unit, a comparison unit and a generation unit.

In some embodiments, the statistical unit may be configured to obtain a statistical parameter of the data row currently processed by the first processor.

In some embodiments, the comparison unit may be configured to compare the statistical parameter with the preset segmentation parameter.

In some embodiments, the comparison unit may be configured to generate the interrupt signal when a preset condition is met.

In some embodiments, the preset segmentation parameter may be determined based on the total number of data contained in a frame and a preset number of slices.

In some embodiments, the slice buffer may include a plurality of slice buffer units.

In some embodiments, the processing unit 23 may be further configured to cause the first processor to sequentially write the slice data into the target slice buffer unit pointed to by the write pointer. When the target slice buffer unit is full, the write pointer may point to the next slice buffer unit of the target slice buffer unit, and the read pointer may point to the target slice buffer unit. The second processor may read the slice data in the target slice buffer unit pointed to by the read pointer.

In some embodiments, the slice buffer may include a plurality of slice buffer units, and each slice buffer unit may store a slice data. The data processing device may further include a writing unit.

In some embodiments, the writing unit may be configured to, after writing the slice data into the last slice buffer unit in the slice buffer, cause the first processor to return to the first slice buffer unit in the slice buffer to perform the next slice data writing operation.

In some embodiments, when the communication link between the first processor and the second processor is started, a portion of the cache in the system-level cache may be used as a slice buffer.

In some embodiments, the transmission unit 21 may be further configured to cause the first processor to transmit the interrupt signal to the CPU. The generation unit may be further configured to cause the CUP to generate a read position for the slice buffer based on the interrupt signal. The reading unit 22 may be further configured to cause the second processor to read the slice data from the reading position.

In some embodiments, the first processor may be a video processing unit or an image processing unit. The second processor may be an artificial intelligence processor (AIPU). The slice data may be video slice data or image slice data.

In some embodiments, the data processing device may be a chip, and the chip may include a first processor, a second processor and a slice buffer. More specifically, in the video processing scenario, the first processor may be a video processing unit; in the image processing scenario, the first processor may be an image processing unit. The second processor may be an AIPU. The slice buffer may be a slice buffer inside the chip, which is used to cache video data or image data required for data processing by the chip. The specific one can be selected based on the actual situation, which is not limited in the embodiments of the present disclosure.

In the present disclosure, the terms “include”, “contain” or other alternatives shall be non-exclusiveness, the inclusion of a series of element such as process, method, object or equipment shall include not only the already mentioned elements but also those elements not mentioned, and shall include the elements which are inherent in the process, method, object or equipment. However, under the condition of no more limitations, the definition of an essential element limited by the sentence “including a . . . ” shall not obviate that in addition to containing the said essential element in the process, method, object or equipment, other essential element of the same nature may also exist in the above-mentioned process, method, object or equipment.

Through the foregoing description of the embodiments, it is clear to those skilled in the relevant art that the present disclosure may be implemented by software plus a universal hardware platform, and may also be implemented by hardware. An electronic apparatus consistent with the disclosure can include a storage medium (for example, a ROM/RAM, a magnetic disk, or an optical disc) storing instructions, and a processor executing the instructions to perform a method consistent with the disclosure, such as one of the above-described methods. The instructions can also instruct a chip to perform the method according to the embodiments of the present disclosure.

The above descriptions are merely example embodiments of the present disclosure, and are not intended to limit the scope of the present disclosure. Any equivalent modification made to the structure or processes based on content of this specification and the accompanying drawings for direct or indirect use in other related technical fields shall all fall within the scope of the present disclosure.

What is claimed is:

1. A chip comprising:
a first processor;
a slice buffer; and
a second processor, wherein:
an output of the first processor is connected to an input of the slice buffer and an input of the second processor respectively, and an output of the slice buffer is also connected to the input of the second processor;
the first processor is configured to write slice data into the slice buffer after the slice data has been processed, and transmit an interrupt signal to the second processor; and
the second processor is configured to read the slice data from the slice buffer based on the interrupt signal, and process the slice data to obtain corresponding result data.

2. The chip of claim 1, wherein:
the first processor includes a comparison unit and a statistical unit, the statistical unit being configured to obtain a statistical parameter of the data currently processed by the first processor, the comparison unit being configured to compare the statistical parameter with a preset segmentation parameter, and generate the interrupt signal when a preset condition is met.

3. The chip of claim 2, wherein:
the preset segmentation parameter is determined based on a total number of data contained in a frame and a preset number of slices.

4. The chip of claim 1, wherein:
the slice buffer includes a plurality of slice buffer units; and
the first processor is configured to sequentially write the slice data into a target slice buffer unit pointed to by a write pointer, when the target slice buffer unit is full, the write pointer points to a next slice buffer unit of the target slice buffer unit, and a read pointer points to the target slice buffer unit; the second processor is configured to read the slice data in the target slice buffer unit pointed to by the read pointer.

5. The chip of claim 1, wherein:
the slice buffer includes a plurality of slice buffer units, each slice buffer unit storing a piece of slice data; and
the first processor is configured to return to a first slice buffer unit in the slice buffer to perform a next slice data writing operation after writing the slice data into a last slice buffer unit in the slice buffer.

6. The chip of claim 1, wherein:
when a communication link between the first processor and the second processor is started, a portion of cache in a system-level cache is used as the slice buffer.

7. The chip of claim 1 further comprising:
a central processing unit (CPU), an input of the CPU being connected to the output of the first processor, and an output of the CPU being connected to the input of the second processor, wherein:
the first processor is configured to transmit the interrupt signal to the CPU;
the CPU is configured to generate a read position for the slice buffer based on the interrupt signal; and
the second processor is configured to read the slice data from the reading position.

8. The chip of claim 1, wherein:
the first processor is a video processing unit or an image processing unit;
the second processor is an artificial intelligence processor (AIPU); and
the slice data the video slice data or image slice data.

9. A data processing method comprising:
writing, by a first processor, slide data into a slice buffer, and transmit an interrupt signal to a second processor after completing a corresponding data processing on the slice data; and
reading, by the second processor, the slice data from the slice buffer based on the interrupt signal, and processing the slice data to obtain corresponding result data.

10. The method of claim 9, before transmitting the interrupt signal to the second processor, the method further comprising:
obtaining, by a statistical unit, a statistical parameter of a data row currently processed by the first processor;
comparing, by a comparison unit, the statistical parameter with a preset segmentation parameter; and
generating the interrupt signal when a preset condition is met.

11. The method of claim 10, wherein:
the preset segmentation parameter is determined based on a total number of data contained in a frame and a preset number of slices.

12. The method of claim 9, wherein:
the slice buffer includes a plurality of slice buffer units; and
the first processor is configured to sequentially write the slice data into a target slice buffer unit pointed to by a write pointer, when the target slice buffer unit is full, the write pointer points to a next slice buffer unit of the target slice buffer unit, and a read pointer points to the target slice buffer unit; the second processor is configured to read the slice data in the target slice buffer unit pointed to by the read pointer.

13. The method of claim 9, wherein:
the slice buffer includes a plurality of slice buffer units, each slice buffer unit storing a piece of slice data; and
the first processor is configured to return to a first slice buffer unit in the slice buffer to perform a next slice data writing operation after writing the slice data into a last slice buffer unit in the slice buffer.

14. The method of claim 9, wherein:
when a communication link between the first processor and the second processor is started, a portion of cache in a system-level cache is used as the slice buffer.

15. The method of claim 9, wherein:
the first processor is configured to transmit the interrupt signal to a central processing unit (CPU), the CPU being configured to generate a read position for the slice buffer based on the interrupt signal; and
the second processor is configured to read the slice data from the reading position.

16. The method of claim 9, wherein:
the first processor is a video processing unit or an image processing unit;
the second processor is an artificial intelligence processor (AIPU); and
the slice data the video slice data or image slice data.

17. A data processing device comprising:
a writing unit, the writing unit being configured to cause a first processor to write slice data into a slice buffer after the slice data has been processed by corresponding data;
a transmission unit, the transmission unit being configured to transmit an interrupt signal to a second processor;
a reading unit, the reading unit being configured to cause the second processor to read the slice data from the slice buffer based on the interrupt signal; and
a processing unit, the processing unit being configured to process the slice data to obtain corresponding result data.

18. The device of claim 17, wherein:
the slice buffer includes a plurality of slice buffer units, each slice buffer unit storing a piece of slice data.

19. The device of claim 17, wherein:
the when a communication link between the first processor and the second processor is started, a portion of cache in a system-level cache is used as the slice buffer.

20. The device of claim 17, wherein:
the first processor is a video processing unit or an image processing unit;
the second processor is an artificial intelligence processor (AIPU); and
the slice data the video slice data or image slice data.
